(19) United States
(12) Patent Application Publication
(10) Pub. No.: US 2026/0033363 A1
(43) Pub. Date: Jan. 29, 2026

(54) SEMICONDUCTOR PACKAGE INCLUDING ANTI-SLIP STRUCTURE

(71) Applicant: SAMSUNG ELECTRONICS CO., LTD., Suwon-si (KR)

(72) Inventors: Sang Cheon PARK, Suwon-si (KR); Un-Byoung KANG, Suwon-si (KR); Kuyoung KIM, Suwon-si (KR); Junwoo MYUNG, Suwon-si (KR); Jeonghwan PARK, Suwon-si (KR); Seung-Jin LEE, Suwon-si (KR)

(73) Assignee: SAMSUNG ELECTRONICS CO., LTD., Suwon-si (KR)

(21) Appl. No.: 19/071,409

(22) Filed: Mar. 5, 2025

(30) Foreign Application Priority Data
Jul. 24, 2024 (KR) 10-2024-0097645

(51) Int. Cl. H01L 23/498; H01L 21/48; H01L 21/56; H01L 23/00; H01L 23/31; H01L 23/538; H01L 25/065; H01L 25/16; H10B 80/00

(52) U.S. Cl. CPC H01L 23/49838; H01L 23/49811; H01L 23/5385; H01L 23/5386; H01L 24/32; H01L 25/0657; H01L 25/16; H01L 21/4853; H01L 21/565; H01L 23/3128; H01L 24/48; H01L 24/73; H01L 24/94; H01L 2224/32145; H01L 2224/32225; H01L 2224/48091; H01L 2224/48227; H01L 2224/73265; H01L 2224/94; H01L 2225/0651; H01L 2225/06517; H01L 2225/06562; H01L 2924/1815; H10B 80/00

(57) ABSTRACT

Disclosed are embodiments of a semiconductor package. The semiconductor package may include: a first substrate; a chip stack on the first substrate, wherein the chip stack comprises one or more semiconductor chips that are stacked to be inclined at a first angle relative to a top surface of the first substrate; a tilt support structure, wherein the tilt support structure is between a first portion of the chip stack and the first substrate; and an anti-slip structure in contact with an end portion of the chip stack.

### CROSS-REFERENCE TO RELATED APPLICATION

The present application claims priority under 35 U.S.C § 119 to Korean Patent Application No. 10-2024-0097645 filed on Jul. 24, 2024 in the Korean Intellectual Property Office, the disclosure of which is hereby incorporated by reference in its entirety.

### BACKGROUND

The present disclosure concepts provide a semiconductor package, and more particularly, to a semiconductor package including an anti-slip structure.

A semiconductor package is provided to implement an integrated circuit chip to qualify for use in electronic products. A semiconductor package is typically configured such that a semiconductor chip is mounted on a printed circuit board (PCB) and bonding wires or bumps are used to electrically connect the semiconductor chip to the printed circuit board. With the development of electronic industry, many studies have been conducted to improve reliability and durability of semiconductor packages.

### SUMMARY

Some embodiments of the present disclosure provide a highly integrated semiconductor package.

The present disclosure is not limited to the mentioned above, and other objects which have not been mentioned above will be clearly understood to those skilled in the art from the following description.

According to some embodiments of the present disclosure, a semiconductor package may include: a first substrate; a chip stack on the first substrate, wherein the chip stack comprises one or more semiconductor chips that are stacked to be inclined at a first angle relative to a top surface of the first substrate; a tilt support structure, wherein the tilt support structure is between a first portion of the chip stack and the first substrate; and an anti-slip structure in contact with an end portion of the chip stack.

According to some embodiments of the present disclosure, a semiconductor package may include: a substrate; a chip stack mounted on the substrate, wherein the chip stack includes one or more semiconductor chips that are stacked to be inclined at a first angle relative to a top surface of the substrate; a plurality of tilt support structures between the chip stack and the substrate, wherein at least one of the plurality of tilt support structure is connected to a first position of a semiconductor chip of the chip stack; a first adhesion layer between the one or more semiconductor chips; and a mold layer that covers the substrate, the chip stack, and the plurality of tilt support structures, wherein the plurality of tilt support structures are spaced apart from each other in a first direction parallel to the top surface of the substrate, and wherein at least one of the plurality of tilt support structures has a top surface inclined at the first angle.

According to some embodiments of the present disclosure, a semiconductor package may include: a first substrate that includes a plurality of substrate conductive pads on a top surface of the first substrate; a chip stack mounted on the first substrate, wherein the chip stack comprises one or more semiconductor chips that are stacked to be inclined at a first angle relative to the top surface of the first substrate, each of the one or more semiconductor chips comprising a front surface, a rear surface opposite to the front surface, and a chip bonding pad on the front surface and adjacent to the first substrate; a plurality of conductive bumps, wherein respective conductive bumps are located between respective substrate conductive pads and respective chip bonding pads, the respective conductive bumps connecting the respective substrate conductive pads to the respective chip bonding pads; a tilt support structure between a first portion of the chip stack and the first substrate; a first adhesion layer between the one or more semiconductor chips; a mold layer that covers the first substrate, the chip stack, and the tilt support structure, and is between the one or more semiconductor chips and the first substrate; and a plurality of external connection terminals bonded to a lower portion of the first substrate, wherein end portions of the one or more semiconductor chips are offset from each other at a same interval, wherein each of the conductive bumps has a top surface that is inclined at the first angle, and wherein the first angle ranges from about 1° to about 30°.

### BRIEF DESCRIPTION OF DRAWINGS

FIG. 1 illustrates a cross-sectional view showing a semiconductor package according to some embodiments of the present disclosure.

FIG. 2 illustrates an enlarged view showing section P1 of FIG. 1.

FIGS. 3A and 3B illustrate perspective views showing tilt support structures and anti-slip structures on a first substrate according to some embodiments of the present disclosure.

FIGS. 4A to 4G illustrate cross-sectional views showing a method of fabricating a semiconductor package of FIG. 1.

FIG. 5 illustrates a cross-sectional view showing a semiconductor package according to some embodiments of the present disclosure.

FIG. 6 illustrates a cross-sectional view showing a semiconductor package according to some embodiments of the present disclosure.

FIG. 7 illustrates a cross-sectional view showing a semiconductor package according to some embodiments of the present disclosure.

FIG. 8 illustrates a cross-sectional view showing a semiconductor package according to some embodiments of the present disclosure.

FIG. 9 illustrates a cross-sectional view showing a semiconductor package according to some embodiments of the present disclosure.

FIG. 10 illustrates a cross-sectional view showing a semiconductor package according to some embodiments of the present disclosure.

FIG. 11 illustrates a cross-sectional view showing a semiconductor package according to some embodiments of the present disclosure.

### DETAILED DESCRIPTION OF EMBODIMENTS

Some embodiments of the present disclosure will now be described in detail with reference to the accompanying drawings to aid in clearly explaining the present disclosure. In this description, such terms as “first” and “second” may be used to simply distinguish identical or similar components from each other, and the sequence of such terms may be changed in accordance with the order of mention.

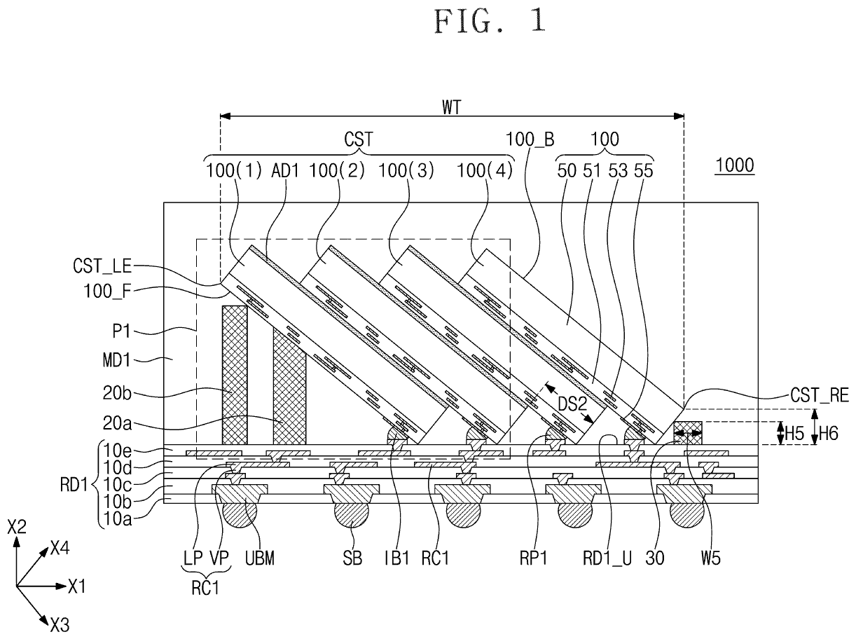

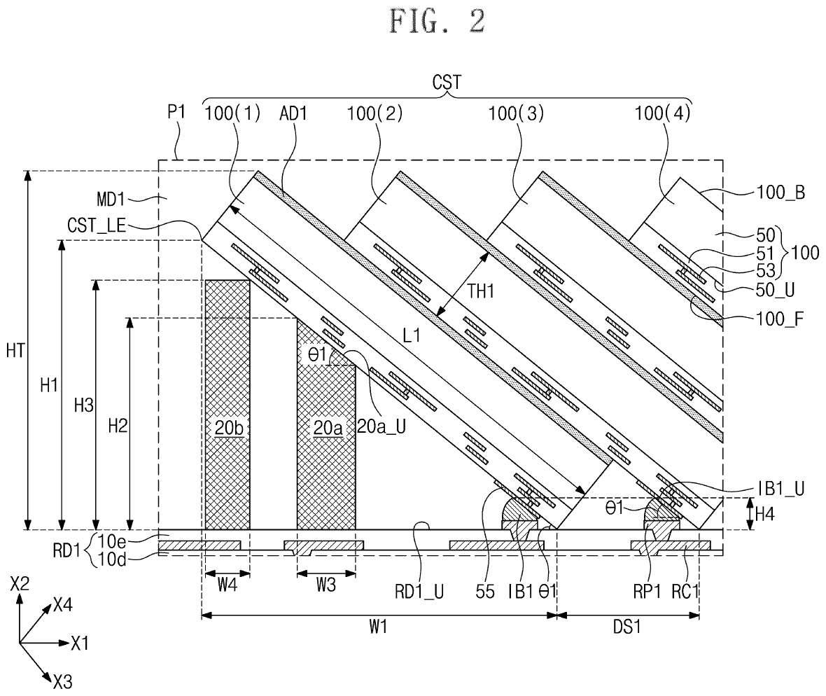

FIG. 1 illustrates a cross-sectional view showing a semiconductor package according to some embodiments of the present disclosure. FIG. 2 illustrates an enlarged view showing section P1 of FIG. 1.

Referring to FIGS. 1 and 2, a semiconductor package 1000 according to the present embodiment may include a first substrate RD1, a chip stack CST, a first mold layer MD1, a tilt support structure 20a and 20b, and an anti-slip structure 30. The first substrate RD1 may be a redistribution substrate, a double-sided printed circuit board (PCB), or multi-layered printed circuit board. In the present embodiment, the first substrate RD1 may be called a first redistribution substrate or first substrate RD1. The first substrate RD1 may include first dielectric layers 10a to 10e, under bumps UBM, first substrate inner patterns RC1, and first substrate conductive pads RP1. The first dielectric layers 10a to 10e may each be, for example, a photo-imageable dielectric (PID).

The under bumps UBM, the first substrate inner patterns RC1, and the first substrate conductive pads RP1 may each be formed of a conductive material. It may be a same or different conductive material. The under bumps UBM, the first substrate inner patterns RC1, and the first substrate conductive pads RP1 may each include a via part VP and a line part LP on the via part VP. The via part VP may have a width that decreases in a downward direction. The under bumps UBM, the first substrate inner patterns RC1, and the first substrate conductive pads RP1 may each include at least one of copper, aluminum, nickel, and gold. The under bumps UBM, the first substrate inner patterns RC1, and the first substrate conductive pads RP1 may each have a bottom surface covered with a diffusion barrier layer. The diffusion barrier layer may be formed of at least one of titanium, titanium nitride, tantalum, and tantalum nitride or any combination thereof.

The under bumps UBM may penetrate a lowermost of the first dielectric layers 10a to 10e, e.g., 10a in FIG. 1. The under bumps UBM may be provided thereon with external connection terminals SB bonded thereto. The external connection terminals SB may be, for example, at least one of solder balls, conductive bumps, and conductive pillars. The external connection terminals SB may include, for example, at least one of tin, nickel, silver, copper, gold, and aluminum.

The first substrate inner patterns RC1 may be interposed between the first dielectric layers 10a to 10e, and may penetrate some of the first dielectric layers 10a to 10e. The first substrate conductive pads RP1 may be positioned on and penetrate an upper layer of the first dielectric layers 10a to 10e, e.g., 10e in FIG. 1.

The chip stack CST may include one or more semiconductor chips 100 that are inclined at a first angle η1 relative to a top surface RD1_U of the first substrate RD1 and overlap each other. The semiconductor chips 100 may be stacked in a fourth direction X4 that is not parallel to the top surface RD1_U of the first substrate RD1. The semiconductor chips 100 may be the same as each other. Each of the semiconductor chips 100 may be called a semiconductor die. Each of the semiconductor chip 100 may be a memory chip, such as a Flash memory chip, a dynamic random access memory (DRAM) chip, a static random access memory (SRAM) chip, an electrically erasable programmable read-only memory (EEPROM) chip, a phase change random access memory (PRAM) chip, a magnetic random access memory (MRAM) chip, or a resistive random access memory (ReRAM) chip.

Each of the semiconductor chips 100 may have a front surface 100_F and a rear surface 100_B that are opposite to each other. Each of the semiconductor chips 100 may have a first thickness TH1 in the fourth direction X4. The front surface 100_F or the rear surface 100_B of each of the semiconductor chips 100 may not be parallel to the top surface RD1_U, and may have a first length L1 in a third direction X3 cross to or perpendicular to the fourth direction X4. The front surface 100_F of each of the semiconductor chips 100 may make the first angle θ1 with the top surface RD1_U of the first substrate RD1. The first angle θ1 may be an acute angle. For example, the first angle θ1 may range from about 1° to about 30°, but the disclosure is not limited thereto.

In the present embodiments, four semiconductor chips 100 may be provided. However, the number of the semiconductor chips 100 included in the chip stack CST is not limited thereto, and may be less than four or greater than five. The chip stack CST may have a chip height HT from the top surface RD1_U of the first substrate RD1 and a chip width WT in a first direction X1 parallel to the top surface RD1_U of the first substrate RD1. The chip width WT may be less than a value obtained by multiplying the number of the semiconductor chips 100 by the first length L1. A leftmost corner CST_LE of the chip stack CST may have a first height H1 from the top surface RD1_U of the first substrate RD1. The first height H1 may be less than the first length L1.

The semiconductor chips 100 may have their end portions that are spaced apart (offset) in the first direction X1 from each other at the same first interval DS1. The end portions of the semiconductor chips 100 may be spaced apart (offset) in the third direction X3 from each other at the same second interval DS2. The chip stack CST may further include a first adhesion layer AD1 interposed between the semiconductor chips 100. The first adhesion layer AD1 may include an epoxy-based material.

Each of the semiconductor chips 100 may include a semiconductor substrate 50, transistors that cove a front surface of the semiconductor substrate 50, an interlayer dielectric layer 51 that covers the transistors, and chip conductive pads 55 disposed on an upper side of the interlayer dielectric layer 51. The front surface 100_F of the semiconductor chip 100 may correspond to an upper side of the interlayer dielectric layer 51. The rear surface 100_B of the semiconductor chip 100 may correspond to a rear surface of the semiconductor substrate 50.

The semiconductor chips 100 may include first to fourth semiconductor chips 100(1) to 100(4) that are disposed sequentially from left to right in FIG. 1. The tilt support structure 20a and 20b may be interposed between the top surface RD1_U of the first substrate RD1 and the front surface 100_F of the first semiconductor chip 100(1) positioned at a leftmost location of the semiconductor chips 100, e.g., leftmost portion of semiconductor chip 100(1). The tilt support structure 20a and 20b may support the chip stack CST. The first semiconductor chip 100(1) may have a first width W1 in the first direction X1.

The tilt support structure 20a and 20b may be provided in plural. For example, the tilt support structure 20a and 20b may include a first tilt support structure 20a and a second tilt support structure 20b that are disposed side by side along a direction opposite to the first direction X1. Each of the first and second support structures 20a and 20b may include a polymeric material, a ceramic material, or a metallic material.

The first tilt support structure 20a and the second tilt support structure 20b may have different shapes from each other. For example, the first tilt support structure 20a may have a trapezoidal cross-section, and the second tilt support structure 20b may have a rectangular cross-section. The first tilt support structure 20a may have a second height H2 from the top surface RD1_U of the first substrate RD1 and a third width W3 in the first direction X1. The second tilt support structure 20b may have a third height H3 from the top surface RD1_U of the first substrate RD1 and a fourth width W4 in the first direction X1. The third height H3 may be greater than the second height H2. The fourth width W4 may be the same as or different from the third width W3. A top surface 20a_U of the first tilt support structure 20a may be inclined at the first angle θ1. In embodiments, the second tilt support structure 20b may be inclined at the first angle.

First inner connection members IB1 may connect the chip conductive pads 55 of the semiconductor chips 100 to correspondingly the first substrate conductive pads RP1. The first inner connection members IB1 may be, for example, at least one of solder balls, conductive bumps, and conductive pillars. The first inner connection members IB1 may each be called a conductive bump. The first inner connection members IB1 may include, for example, at least one of tin, nickel, silver, copper, gold, and aluminum. A top surface of each of the first inner connection members IB1 may be in contact with a corresponding chip conductive pad 55 and may be inclined at the first angle θ1. The first inner connection members IB1 may have their upper sides that are located at a fourth height H4 from the top surface RD1_U of the first substrate RD1.

An end portion (e.g., a right end portion as shown in FIG. 1) of the chip stack CST may be in contact with the anti-slip structure 30. The anti-slip structure 30 may prevent slippage of the chip stack CST. In the present embodiment, the semiconductor substrate 50 of the fourth semiconductor chip 100(4) positioned on a rightmost location among the semiconductor chips 100 of the chip stack CST may have a lateral surface in contact with an upper corner of the anti-slip structure 30. The anti-slip structure 30 may include a polymeric material, a ceramic material, or a metallic material. The anti-slip structure 30 may have a fifth width W5 in the first direction X1 and a fifth height H5 from the top surface RD1_U of the first substrate RD1. A rightmost corner CST_RE of the chip stack CST may have a sixth height H6 from the top surface RD1_U of the first substrate RD1. The fifth height H5 may be less than the sixth height H6.

The following relationships may be expressed between the first angle θ1, the first height H1, the second height H2, the third height H3, the fifth height H5, the first thickness TH1, the first length L1, the first interval DS1, the second interval DS2, the first width W1, the third width W3, the fourth width W4, the fifth width W5, the chip width WT, and the number N of the semiconductor chips 100 included in the chip stack CST.

$$sin θ1 = H 1 / L1 \to θ1 = {sin}^{- 1} ( H 1 / L 1 ) \qquad Eqn ( 1 )$$

$$tan θ1 = TH 1 / DS 2 \to DS 2 = TH 1 / tan θ1 \qquad Eqn ( 2 )$$

$$cos θ1 = W 1 / L 1 \to W 1 = L 1 \cdot cos θ1 \qquad Eqn ( 3 )$$

$$cos θ1 = D S 2 / DS 1 \to DS 1 = DS 2 / cos θ1 \qquad Eqn ( 4 )$$

$$W 4 or W 3 < W 1 - DS 1 \qquad Eqn ( 5 )$$

$$H 2 or H 3 < HT - ( TH 1 \cdot cos θ1 ) \qquad Eqn ( 6 )$$

$$W 5 < W 1 - DS 1 \qquad Eqn ( 7 )$$

$$\begin{matrix}H 5 < TH 1 \cdot cos θ1 & Eqn ( 8 )\end{matrix}$$

$$WT = W 1 + D S 1 ( N - 1 ) \qquad Eqn ( 9 )$$

The first mold layer MD1 may cover the first substrate RD1, the chip stack CST, the tilt support structures 20a and 20b, and the anti-slip structure 30. The first mold layer MD1 may fill a space between the chip stack CST and the first substrate RD1, a space between the tilt support structures 20a and 20b, and a space between the chip stack CST and the anti-slip structure 30. The first mold layer MD1 may include a dielectric resin, such as an epoxy molding compound (EMC). The first mold layer MD1 may further include fillers, and the fillers may be dispersed in the dielectric resin.

In the semiconductor package 1000 according to the present disclosure, as the semiconductor chips 100 are stacked inclined with respect to the top surface RD1_U of the first substrate RD1, the semiconductor package 1000 may have a reduced horizontal width. In addition, the semiconductor package 1000 according to the present disclosure may include the tilt support structure 20a and 20b and the anti-slip structure 30, the chip stack CST may be effectively supported without slippage. Thus, the semiconductor package 1000 may be provided with high integration and increased capacity. Moreover, the first inner connection members IB1 through which the semiconductor chips 100 is connected to the first substrate RD1 may have their heights less than those of wires, an increased signal transfer speed may be provided between the semiconductor chips 100 and the first substrate RD1. Furthermore, no wires may be used to avoid collapse of wires and to miniaturize sizes of the first inner connection members IB1. Accordingly, it may be possible to improve reliability of the semiconductor package 1000 and to increase the number of input/output terminals.

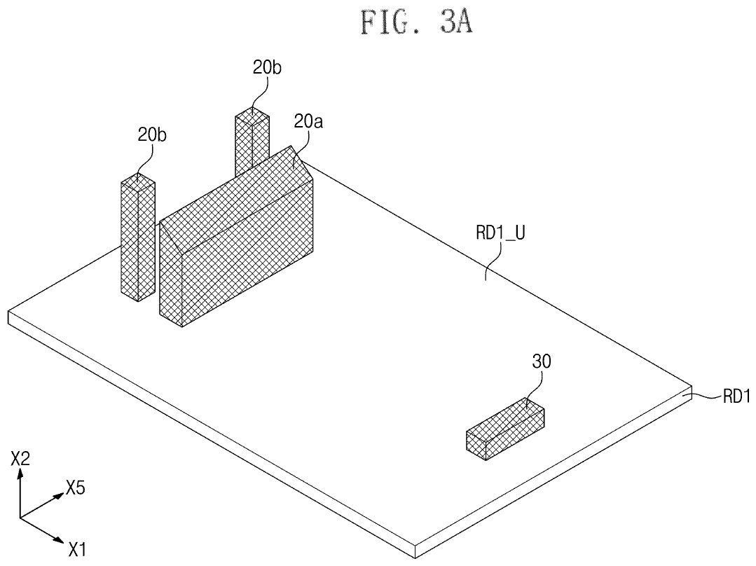

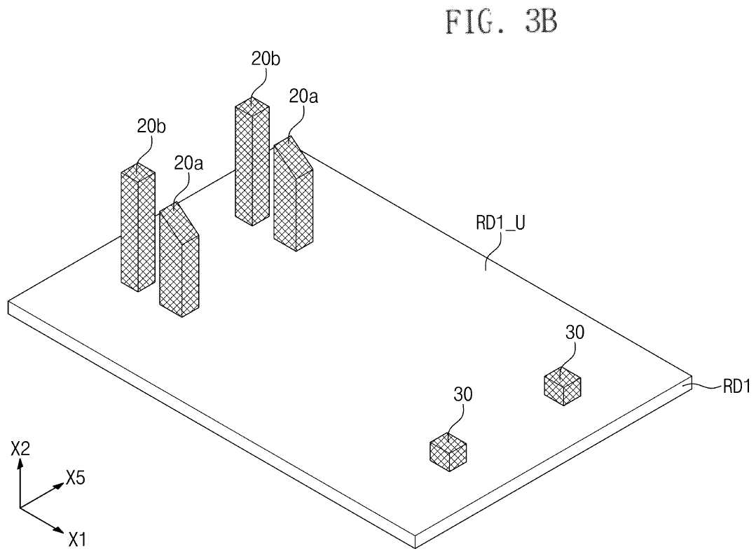

FIGS. 3A and 3B illustrate perspective views showing tilt support structures and anti-slip structures on a first substrate according to some embodiments of the present disclosure.

Referring to FIG. 3A, when viewed in plan, the first tilt support structure 20a and the anti-slip structure 30 may each have a bar shape that is elongated along a fifth direction X5 parallel to the top surface RD1_U of the first substrate RD1 and cross to the first direction X1. The second tilt support structure 20b may be provided in plural. The second tilt support structures 20b may have their pillar shapes and may be spaced apart from each other along the fifth direction X5.

Referring to FIG. 3B, the first tilt support structure 20a may be provided in plural. The first tilt support structures 20a may have their pillar shapes and may be spaced apart from each other along the fifth direction X5. The anti-slip structure 30 may be provided in plural. The anti-slip structures 30 may have their rectangular hexahedral shapes and may be spaced apart from each other along the fifth direction X5. The distance between the plurality of first tilt support structures 20a, second tilt support structures 20b, and anti-slip structure 30 long the fifth direction X5 may be same or may be different for each structure. An arrangement and structures of the first tilt support structure 20a, the second tilt support structure 20b, and the anti-slip structure 30 may prevent voids during the formation of the first mold layer MD1 and also stably support the chip stack CST.

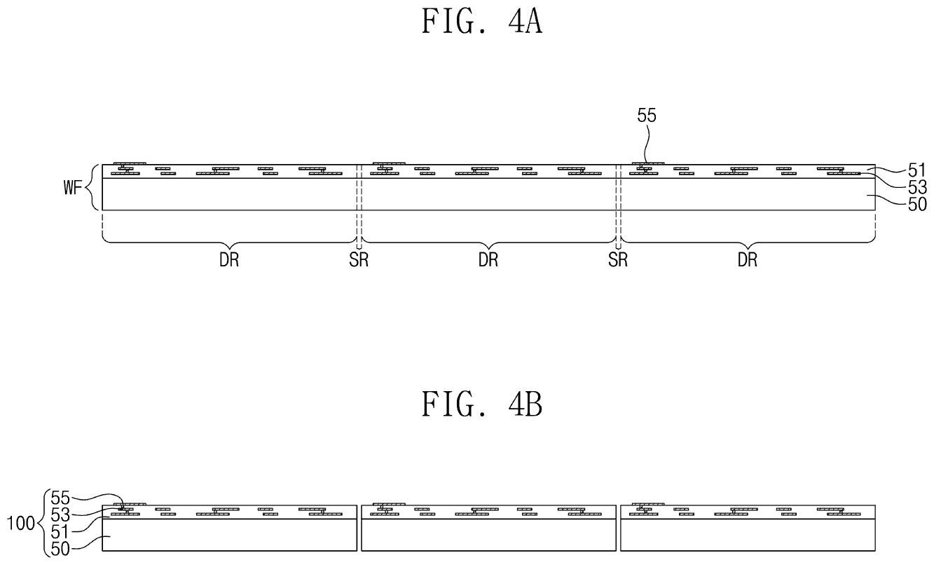

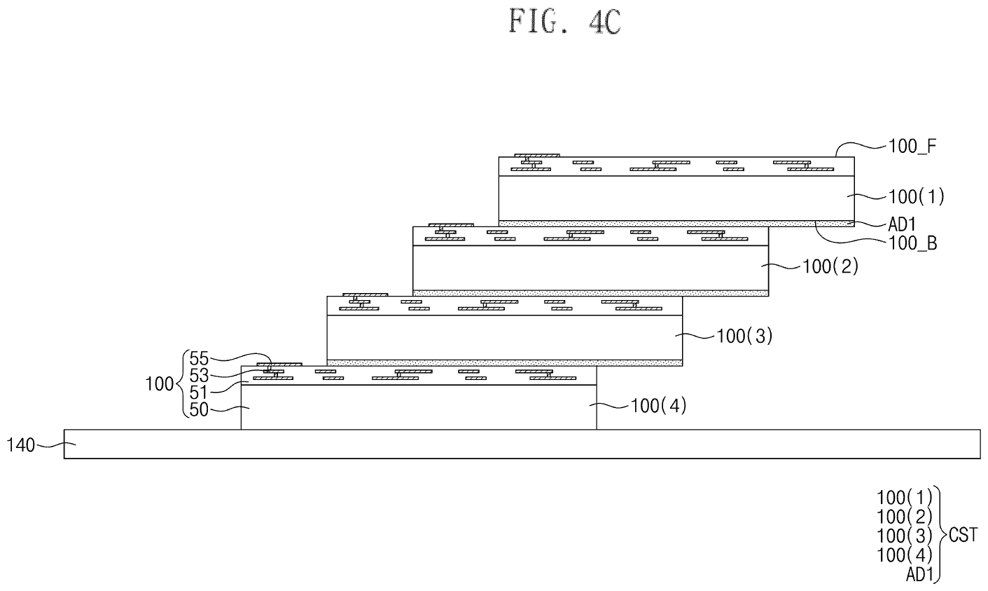

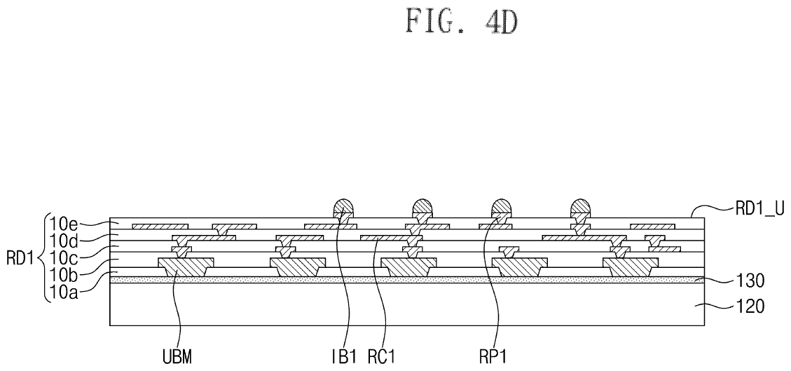

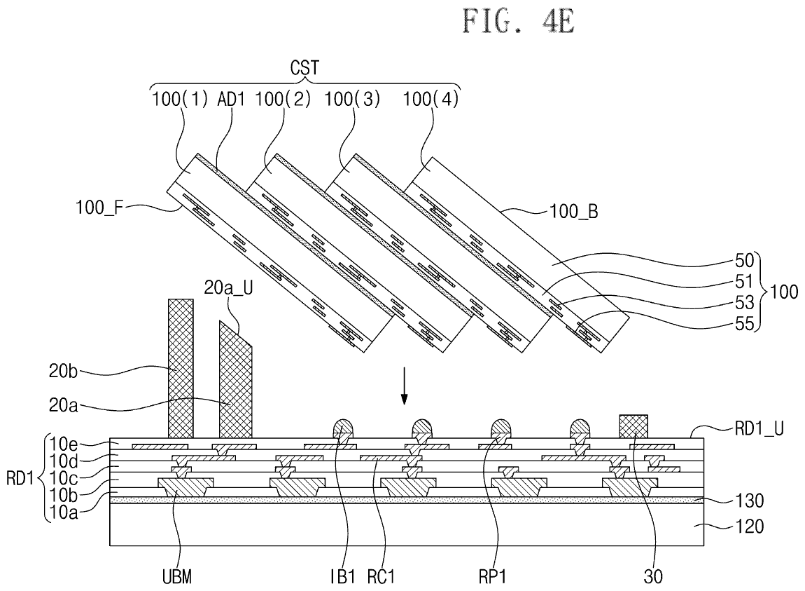

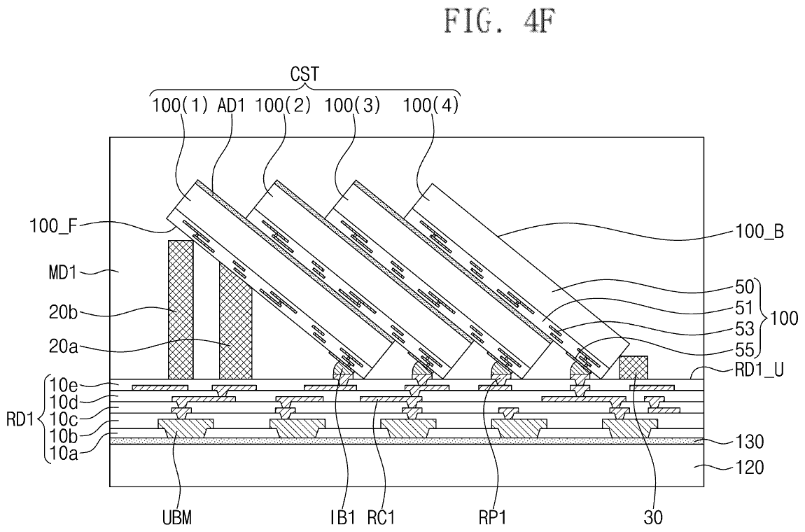

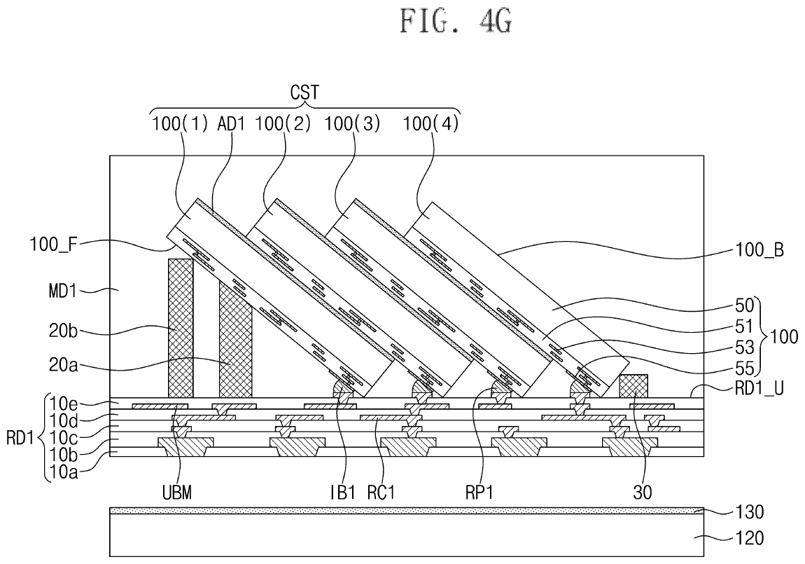

FIGS. 4A to 4G illustrate cross-sectional views showing a method of fabricating a semiconductor package of FIG. 1.

Referring to FIG. 4A, a wafer WF may be prepared for forming semiconductor chips (see 100 of FIG. 1). The wafer WF may include a semiconductor substrate 50. The wafer WF may include device regions DR and a separation region SR between the device regions DR. Transistors, wiring lines 53, interlayer dielectric layers 51, and chip conductive pads 55 may be disposed on a front surface of the semiconductor substrate 50. On the device regions DR, the transistors, the wiring lines 53, and the chip conductive pads 55 may have their structures the same as that of the semiconductor chip 100 of FIG. 1.

Referring to FIGS. 4A and 4B, a sawing process may be performed to cut the separation region SR of the wafer WF. Thus, the device regions DR of the wafer WF may become semiconductor chips 100.

Referring to FIG. 4C, the semiconductor chips 100 may be stacked on a tape 140. A first adhesion layer AD1 may be interposed between the semiconductor chips 100. The semiconductor chip 100 may have their end portions that form a stepwise shape, and the chip conductive pads 55 of the semiconductor chips 100 may be exposed. Therefore, a chip stack CST may be formed.

Referring to FIG. 4D, a sacrificial substrate 120 may be prepared. For example, the sacrificial substrate 120 may be a tape, a transparent glass substrate, or a bare wafer. A sacrificial layer 130 may be formed on the sacrificial substrate 120. The sacrificial layer 130 may include an epoxy resin. The sacrificial layer 130 may exhibit, for example, photodegradability or thermodegradability. A first substrate RD1 may be formed on the sacrificial layer 130. The first substrate RD1 may include first dielectric layers 10a to 10e, under bumps UBM, first substrate inner patterns RC1, and first substrate conductive pads RP1.

For example, the first dielectric layers 10a to 10e may each be formed of a photo-imageable dielectric (PID), and may be formed by coating, baking, exposure, and development processes. The under bumps UBM, the first substrate inner patterns RC1, and the first substrate conductive pads RP1 may each be formed by a plating process. The first substrate conductive pads RP1 may be formed on an uppermost one 10e of the first dielectric layers 10a to 10e. First inner connection members IB1 may be formed on the first substrate conductive pads RP1. The first inner connection members IB1 may be one or more of conductive bumps and solder balls.

Referring to FIGS. 4C to 4E, a first tilt support structure 20a, a second tilt support structure 20b, and an anti-slip structure 30 may be formed on the first substrate RD1. The chip stack CST of FIG. 4C may be separated from the tape 140, and may be turned upside down to allow the chip conductive pads 55 to contact the first inner connection members IB1. The semiconductor chips 100 of the chip stack CST may be mounted inclined at a first angle θ1 relative to a top surface RD1_U of the first substrate RD1 as shown in FIG. 1. In this configuration, a left lower inclined surface of the chip stack CST may be in contact with the first tilt support structure 20a and the second tilt support structure 20b, and a right end portion of the chip stack CST may be in contact with the anti-slip structure 30. However, it may be understood that the present disclosure is not limited thereto. A reflow process may be performed to bond the first inner connection members IB1 to the chip conductive pads 55.

Referring to FIG. 4F, a first mold layer MD1 may be formed to cover the first substrate RD1, the chip stack CST, the tilt support structure 20a and 20b, and the anti-slip structure 30.

Referring to FIG. 4G, the sacrificial substrate 120 and the sacrificial layer 130 may be detached from a bottom surface of the first substrate RD1. Referring to FIG. 1, external connection terminals SB may be bonded to the under bumps UBM. A singulation process may be performed to fabricate a semiconductor package 1000.

In the method of fabricating a semiconductor package according to the present disclosure, the tilt support structure 20a and 20b, and the anti-slip structure 30 may be used to prevent slippage of the semiconductor chips 100 and to stably perform processes. As a result, process failure may be reduced to increase a yield.

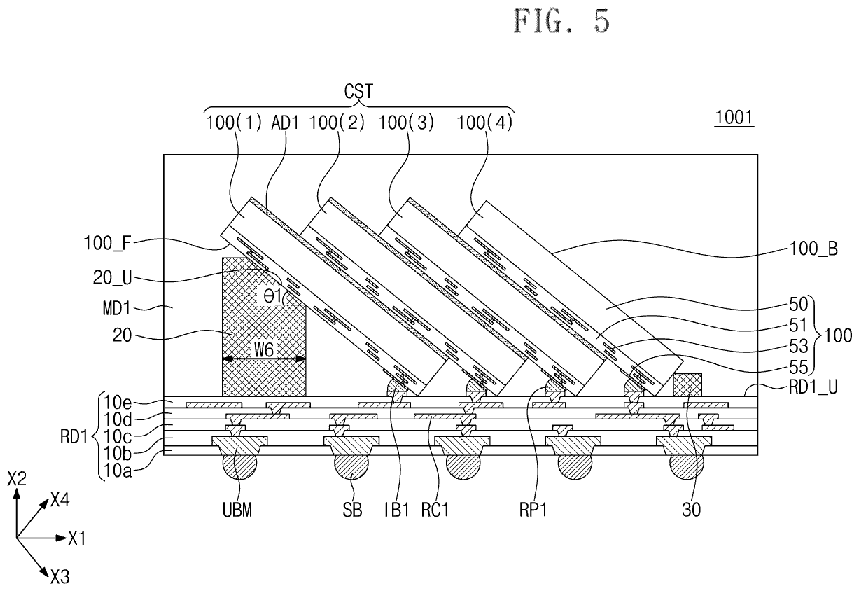

FIG. 5 illustrates a cross-sectional view showing a semiconductor package according to some embodiments of the present disclosure.

Referring to FIG. 5, a semiconductor package 1001 according to the present embodiment may include a single tilt support structure 20. A width W6 of the tilt support structure 20 according to the present embodiment may be greater than the width W3 of the first tilt support structure 20a of FIG. 2 or the width W4 of the second tilt support structure 20b of FIG. 2. The tilt support structure 20 having the width W6 may have a top surface 20_U inclined at the first angle θ1. Other configurations may be identical or similar to those discussed with reference to FIGS. 1 to 3B.

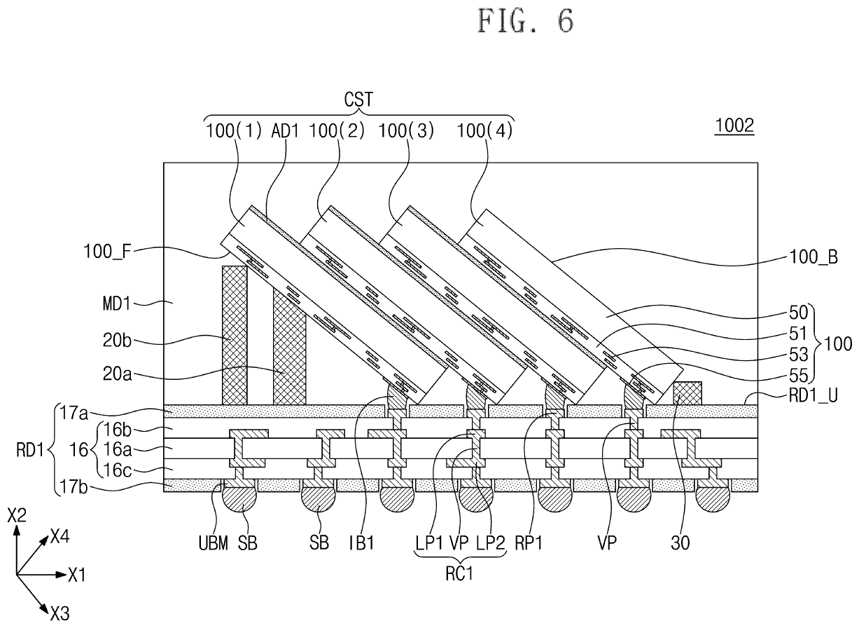

FIG. 6 illustrates a cross-sectional view showing a semiconductor package according to some embodiments of the present disclosure.

Referring to FIG. 6, in a semiconductor package 1002 according to the present embodiment, the first substrate RD1 may be a multi-layered printed circuit board. The first substrate RD1 may include a substrate body 16, an upper photosensitive dielectric layer 17a, and a lower photosensitive dielectric layer 17b. The substrate body 16 may include multi-layered substrate dielectric layers 16a to 16c. The substrate body 16 may include a first substrate dielectric layer 16a, a second substrate dielectric layer 16b disposed on a top surface of the first substrate dielectric layer 16a, and a third substrate dielectric layer 16c disposed on a bottom surface of the first substrate dielectric layer 16a. The substrate dielectric layers 16a to 16c may be formed of a thermosetting resin such as epoxy resin, a thermoplastic resin such as polyimide, a resin (e.g., prepreg) in which a thermosetting or thermoplastic resin is impregnated with a reinforcement such as glass fiber and/or inorganic filler, and/or a photo-curable resin, but the present disclosure are not especially limited thereto. A photo-solder resist (PSR) may be used to form the upper photosensitive dielectric layer 17a and the lower photosensitive dielectric layer 17b. A first substrate dielectric layer 16a may be called a core layer.

Each of the first substrate inner patterns RC1 may include a via part VP that penetrates the first substrate dielectric layer 16a, a first line part LP disposed on the via part VP, and a second line part LP2 disposed beneath the via part VP. The under bumps UBM may each include a via part VP that penetrates a third substrate dielectric layer 16c. The first substrate conductive pads RP1 may each include a via part VP that penetrates a second substrate dielectric layer 16b.

The tilt support structure 20a and 20b and the anti-slip structure 30 may be disposed on the upper photosensitive dielectric layer 17a. Other configurations may be identical or similar to those discussed with reference to FIGS. 1 to 5.

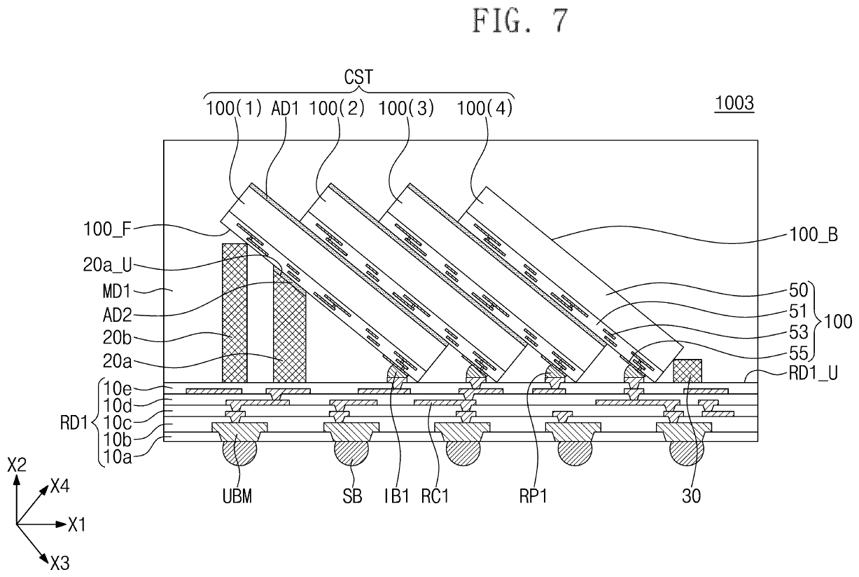

FIG. 7 illustrates a cross-sectional view showing a semiconductor package according to some embodiments of the present disclosure.

Referring to FIG. 7, in a semiconductor package 1003 according to the present embodiment, a second adhesion layer AD2 may be interposed between the top surface 20a_U of the first tilt support structure 20a and the front surface 100_F of the first semiconductor chip 100(1) of the chip stack CST shown in FIG. 1. The second adhesion layer AD2 may prevent slippage of the chip stack CST. The second adhesion layer AD2 may be formed of, for example, an epoxy-based material. Other configurations may be identical or similar to those discussed with reference to FIGS. 1 to 6.

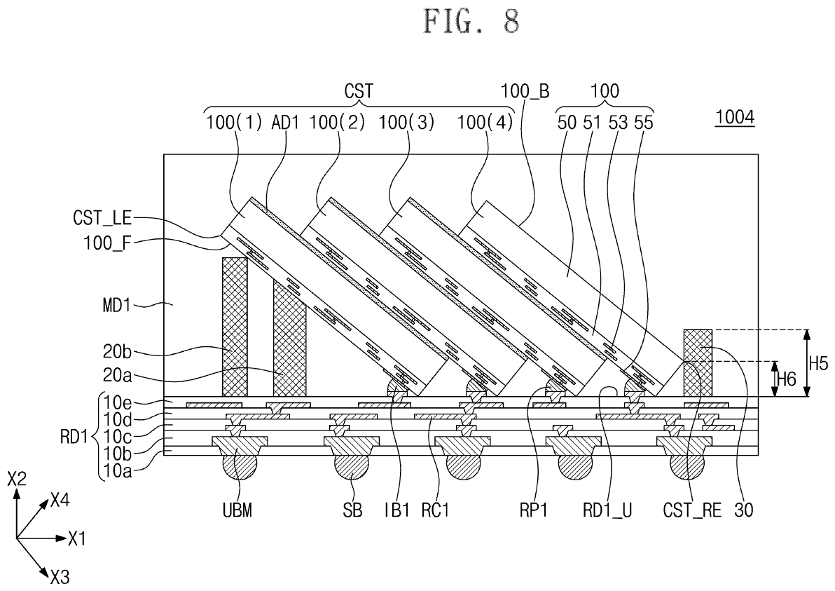

FIG. 8 illustrates a cross-sectional view showing a semiconductor package according to some embodiments of the present disclosure.

Referring to FIG. 8, in a semiconductor package 1004 according to the present embodiment, the anti-slip structure 30 may be in contact with the rightmost corner CST_RE of the chip stack CST. The anti-slip structure 30 may have a fifth height H5 from the top surface RD1_U of the first substrate RD1. The rightmost corner CST_RE of the chip stack CST may have a sixth height H6 from the top surface RD1_U of the first substrate RD1. The fifth height H5 may be greater than the sixth height H6. Other configurations may be identical or similar to those discussed with reference to FIGS. 1 to 7.

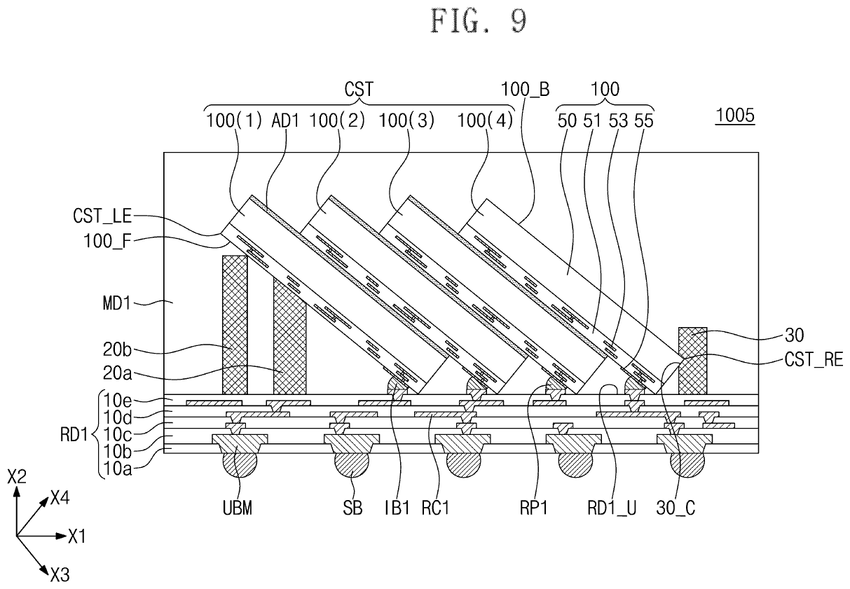

FIG. 9 illustrates a cross-sectional view showing a semiconductor package according to some embodiments of the present disclosure.

Referring to FIG. 9, in a semiconductor package 1005 according to the present embodiment, the anti-slip structure 30 may have a lateral surface including a recess 30_C into which the rightmost corner CST_RE of the chip stack CST is inserted. Thus, the anti-slip structure 30 prevents slippage of the chip stack CST and also rigidly holds the chip stack CST. Other configurations may be identical or similar to those discussed with reference to FIGS. 1 to 8.

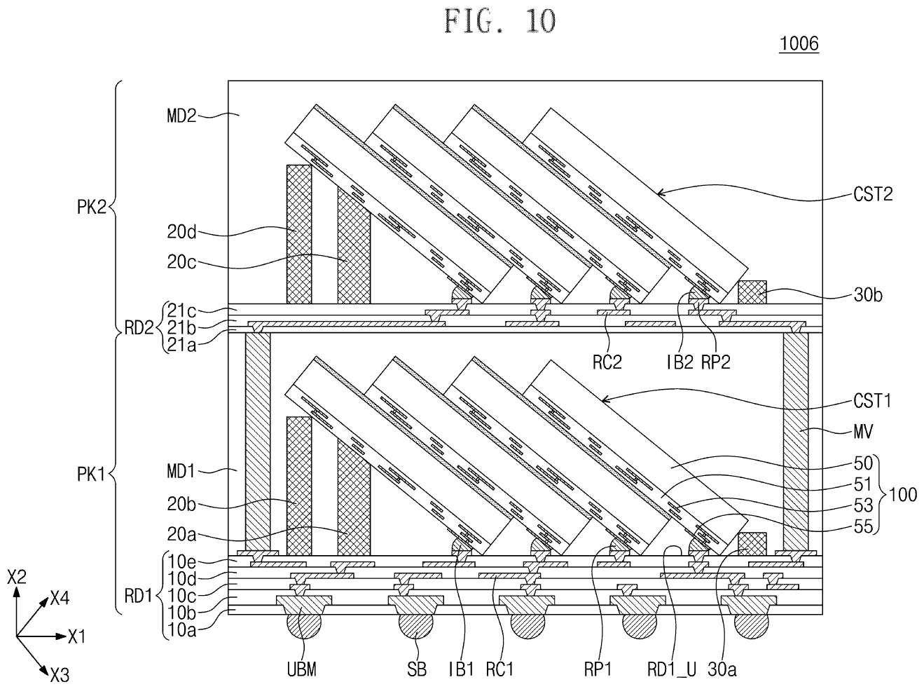

FIG. 10 illustrates a cross-sectional view showing a semiconductor package according to some embodiments of the present disclosure.

Referring to FIG. 10, a semiconductor package 1006 according to the present embodiment may have a package-on-package structure in which a second sub-semiconductor package PK2 is stacked on a first sub-semiconductor package PK1. The first sub-semiconductor package PK1 may have a structure of FIG. 1 to which mold vias MV are added. The first sub-semiconductor package PK1 may include a first substrate RD1, a first chip stack CST1, first and second tilt support structures 20a and 20b, a first anti-slip structure 30a, a first mold layer MD1, and mold vias MV. The first substrate RD1, the first chip stack CST1, the first and second tilt support structures 20a and 20b, the first anti-slip structure 30a, and the first mold layer MD1 may have the same structures as those discussed with reference to FIG. 1.

The mold vias MV may be formed of metal, such as copper. The mold vias MV may penetrate the first mold layer MD1 to come into contact with some of the first substrate conductive pads RP1. The mold vias MV may be disposed closer to an edge of the semiconductor package 1006 than the first and second tilt support structures 20a and 20b and the first anti-slip structure 30a.

A second sub-semiconductor package PK2 may include a second substrate RD2, a second chip stack CST2, a second mold layer MD2, third and fourth tilt support structures 20c and 20d, and a second anti-slip structure 30b.

The second substrate RD2 may include second dielectric layers 21a to 21c, second substrate inner patterns RC2, and second substrate conductive pads RP2. The second dielectric layers 21a to 21c may each be, for example, a photo-imageable dielectric (PID). The second substrate inner patterns RC2 and the second substrate conductive pads RP2 may each be formed of a conductive material. The second substrate inner patterns RC2 and the second substrate conductive pads RP2 may each include at least one of titanium, titanium nitride, tantalum, tantalum nitride, copper, aluminum, nickel, and gold.

The second chip stack CST2 may have the same structure as that of the first chip stack CST1. Second inner connection members IB2 may connect the chip conductive pads 55 of the second chip stack CST2 to the second substrate conductive pads RP2. The third and fourth tilt support structures 20c and 20d and the second anti-slip structure 30b may have the same structures as those of the first and second support structures 20a and 20b and the first anti-slip structure 30a, respectively.

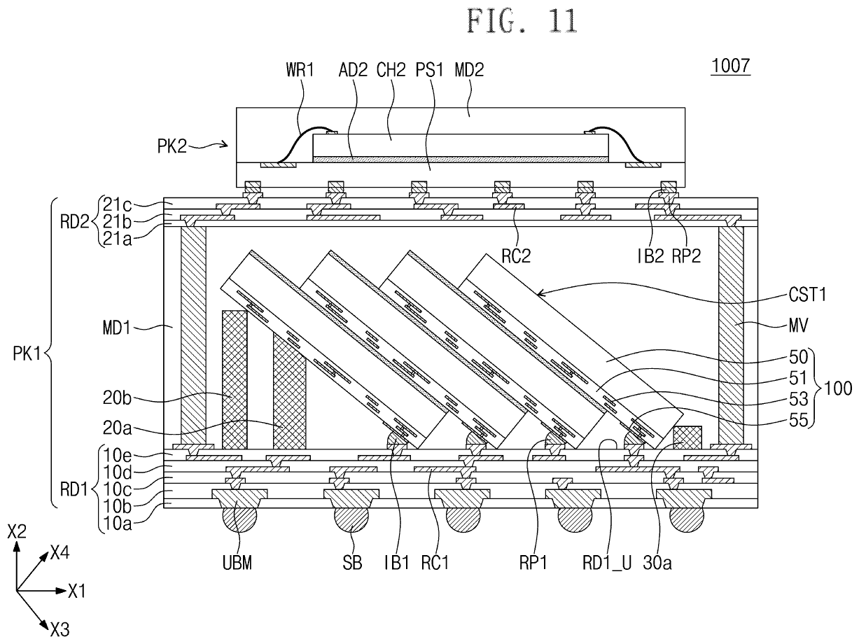

FIG. 11 illustrates a cross-sectional view showing a semiconductor package according to some embodiments of the present disclosure.

Referring to FIG. 11, a semiconductor package 1007 according to the present embodiment may have a package-on-package structure in which a second sub-semiconductor package PK2 is stacked on a first sub-semiconductor package PK1. The first sub-semiconductor package PK1 may have a structure of FIG. 1 to which mold vias MV and a second substrate RD2 are added.

The second sub-semiconductor package PK2 may be bonded through second inner connection members IB2 to second substrate conductive pads RP2 of the second substrate RD2 in the first sub-semiconductor package PK1. The second sub-semiconductor package PK2 may include a first sub-package substrate PS1, a second semiconductor device CH2 disposed on the first sub-package substrate PS1, a second adhesion layer AD2 interposed between the first sub-package substrate PS1 and the second semiconductor device CH2, a second mold layer MD2 that covers the first sub-package substrate PS1 and the second semiconductor device CH2, and first wires WRI that connect the first sub-package substrate PSI to the second semiconductor device CH2. The first sub-package substrate PSI may be a double-sided or multi-layered printed circuit board. Alternatively, the first sub-package substrate PS1 may be a redistribution substrate. The second semiconductor device CH2 may be, for example, one selected from an image sensor chip such as CMOS image sensor (CIS), a microelectromechanical system (MEMS) device chip, an application specific integrated circuit (ASIC) chip, and a memory device chip such as Flash memory, DRAM, SRAM, EEPROM, PRAM, MRAM, ReRAM, HBM (high bandwidth memory), and HMC (hybrid memory cubic). Other configurations may be identical or similar to those discussed above with reference to FIG. 10.

In a semiconductor package according to the present disclosure, as semiconductor chips are stacked inclined with respect to a top surface of a substrate, the semiconductor package may have a reduced horizontal width. In addition, as the semiconductor package according to the present disclosure has a tilt support structure and an anti-slip structure, it may be possible to prevent slippage of a chip stack and to effectively support the chip stack. As a result, the semiconductor package may be provided with high integration and increased capacity.

Although the present invention has been described in connection with some embodiments of the present disclosure illustrated in the accompanying drawings, it will be understood to those skilled in the art that various changes and modifications may be made without departing from the technical spirit and essential feature of the present disclosure. It will be apparent to those skilled in the art that various substitution, modifications, and changes may be thereto without departing from the scope and spirit of the present disclosure. The embodiments of FIGS. 1 to 11 may be combined with each other.

What is claimed is:

1. A semiconductor package, comprising:
a first substrate;
a chip stack on the first substrate, wherein the chip stack comprises one or more semiconductor chips that are stacked to be inclined at a first angle relative to a top surface of the first substrate;
a tilt support structure, wherein the tilt support structure is between a first portion of the chip stack and the first substrate; and
an anti-slip structure in contact with an end portion of the chip stack.

2. The semiconductor package of claim 1, wherein the tilt support structure includes a first sub-support structure and a second sub-support structure that are spaced apart from each other, and
wherein a shape of the first sub-support structure is different from a shape of the second sub-support structure.

3. The semiconductor package of claim 2, wherein a top surface of at least one of the first sub-support structure and the second sub-support structure is inclined at the first angle.

4. The semiconductor package of claim 1, wherein each of the tilt support structure and the anti-slip structure comprises at least one of a polymeric material, a ceramic material, or a metallic material.

5. The semiconductor package of claim 1, further comprising an adhesion layer between at least some portion of the tilt support structure and the chip stack.

6. The semiconductor package of claim 1, wherein the first angle ranges from about 1° to about 30°.

7. The semiconductor package of claim 1,
wherein each of the one or more semiconductor chips comprises:
a front surface and a rear surface that are opposite to each other; and
a chip bonding pad on the front surface and adjacent to the first substrate,
wherein the first substrate includes a plurality of substrate conductive pads that are correspondingly adjacent to a plurality of chip bonding pads of the one or more semiconductor chips,
wherein the semiconductor package further comprises a plurality of conductive bumps such that respective conductive bumps are located between respective substrate conductive pads and respective chip bonding pads, the respective conductive bumps connecting the respective substrate conductive pads to the respective chip bonding pads, and
wherein a top surface of each of the conductive bumps is inclined at the first angle.

8. The semiconductor package of claim 1, wherein end portions of the one or more semiconductor chips are offset from each other at the same interval.

9. The semiconductor package of claim 1, further comprising:
a mold layer that covers the first substrate, the chip stack, the tilt support structure, and the anti-slip structure;
a second substrate on the mold layer;
a mold via that penetrates the second substrate; and
a semiconductor device on the second substrate.

10. The semiconductor package of claim 1, wherein the chip stack further comprises an adhesion layer between the one or more semiconductor chips.

11. A semiconductor package, comprising:
a substrate;
a chip stack mounted on the substrate, wherein the chip stack comprises one or more semiconductor chips that are stacked to be inclined at a first angle relative to a top surface of the substrate;
a plurality of tilt support structures between the chip stack and the substrate, wherein at least one of the plurality of tilt support structure is connected to a first position of a semiconductor chip of the chip stack;
a first adhesion layer between the one or more semiconductor chips; and
a mold layer that covers the substrate, the chip stack, and the plurality of tilt support structures,
wherein the plurality of tilt support structures are spaced apart from each other in a first direction parallel to the top surface of the substrate, and
wherein at least one of the plurality of tilt support structures has a top surface inclined at the first angle.

12. The semiconductor package of claim 11, further comprising an anti-slip structure between the chip stack and the substrate.

13. The semiconductor package of claim 11, wherein the plurality of tilt support structures include a first tilt support structure and a second tilt support structure, and
wherein a shape of the first tilt support structure is different from a shape of the second tilt support structure.

14. The semiconductor package of claim 11,
wherein each of the one or more semiconductor chips comprises:
a front surface and a rear surface that are opposite to each other; and
a chip bonding pad on the front surface and adjacent to the substrate,
wherein the substrate includes a plurality of substrate conductive pads that are correspondingly adjacent to a plurality of chip bonding pads of the one or more semiconductor chips,
wherein the semiconductor package further comprises a plurality of conductive bumps such that respective conductive bumps are located between respective substrate conductive pads and respective chip bonding pads, the respective conductive bumps connecting the respective substrate conductive pads to the respective chip bonding pads, and
wherein a top surface of each of the conductive bumps is inclined at the first angle.

15. The semiconductor package of claim 11, further comprising a second adhesion layer between at least one tilt support structure and the chip stack.

16. A semiconductor package, comprising:
a first substrate that includes a plurality of substrate conductive pads on a top surface of the first substrate;
a chip stack mounted on the first substrate, wherein the chip stack comprises one or more semiconductor chips that are stacked to be inclined at a first angle relative to the top surface of the first substrate, each of the one or more semiconductor chips comprising a front surface, a rear surface opposite to the front surface, and a chip bonding pad on the front surface and adjacent to the first substrate;
a plurality of conductive bumps, wherein respective conductive bumps are located between respective substrate conductive pads and respective chip bonding pads, the respective conductive bumps connecting the respective substrate conductive pads to the respective chip bonding pads;
a tilt support structure between a first portion of the chip stack and the first substrate;
a first adhesion layer between the one or more semiconductor chips;
a mold layer that covers the first substrate, the chip stack, and the tilt support structure, and is between the one or more semiconductor chips and the first substrate; and
a plurality of external connection terminals bonded to a lower portion of the first substrate,
wherein end portions of the one or more semiconductor chips are offset from each other at a same interval,
wherein each of the conductive bumps has a top surface that is inclined at the first angle, and
wherein the first angle ranges from about 1° to about 30°.

17. The semiconductor package of claim 16, further comprising an anti-slip structure between an end portion of the chip stack and the first substrate.

18. The semiconductor package of claim 16, wherein the tilt support structure includes a first tilt support structure and a second tilt support structure, and
wherein a shape of the first tilt support structure is different from a shape of the second tilt support structure.

19. The semiconductor package of claim 16, further comprising an adhesion layer between a portion of the tilt support structure and the chip stack.

20. The semiconductor package of claim 16, further comprising:
a second substrate on the mold layer;
a mold via that penetrates the second substrate; and
a semiconductor device on the second substrate.
